(19) United States
(12) Patent Application Publication
(10) Pub. No.: US 2013/0270104 A1
(43) Pub. Date: Oct. 17, 2013

(54) COMBINATORIAL PROCESSING USING MOSAIC SPUTTERING TARGETS

(71) Applicants: Hong Sheng Yang, Pleasanton, CA (US); Chi-l Lang, Cupertino, CA (US); Yun Wang, San Jose, CA (US)

(72) Inventors: Hong Sheng Yang, Pleasanton, CA (US); Chi-l Lang, Cupertino, CA (US); Yun Wang, San Jose, CA (US)

(73) Assignee: Intermolecular, Inc., San Jose, CA (US)

(21) Appl. No.: 13/444,100

(22) Filed: Apr. 11, 2012

(51) Int. Cl. C23C 14/35

(52) U.S. Cl. 204/192.1; 204/298.12; 204/298.11

(57) ABSTRACT

Embodiments of the present invention provide methods and apparatuses using sputtering from a mosaic sputtering target for depositing layers onto a substrate, and provide the capability of depositing layers onto site isolated regions of the substrate in a combinatorial manner. A sputtering source is provided including a sputtering target comprising a first region having a first composition, and a second region having a second composition. A selection mechanism is capable of selecting a composition of emitted material from the sputtering source that can range from 0% to 100% of the first composition and from 0% to 100% of the second composition. The selection mechanism can comprise a movable magnetron or a moveable aperture.

### CROSS REFERENCE TO RELATED APPLICATION

This application is related to co-owned U.S. patent application Ser. No. 13/339,649 entitled “Combinatorial Processing Using High Deposition Rate Sputtering,” filed on Dec. 29, 2011 and co-owned U.S. patent application Ser. No. 13/281,316 entitled “High Metal Ionization Sputter Gun,” filed on Oct. 25, 2011, which are incorporated herein by reference.

### FIELD OF THE INVENTION

One or more embodiments of the present invention relate to methods and apparatuses for combinatorial processing using sputtering from mosaic sputtering targets for thin film deposition.

### BACKGROUND

Physical vapor deposition (PVD) is commonly used within the semiconductor industry as well as within solar, glass coating, and other industries, in order to deposit a layer over a substrate. Sputtering is a common physical vapor deposition method, where atoms or molecules are emitted from a target material by high-energy particle bombardment and then deposited onto the substrate.

In order to identify different materials, evaluate different unit process conditions or parameters, or evaluate different sequencing and integration of processes, and combinations thereof, it may be desirable to be able to process different regions of the substrate differently. This capability, hereinafter called “combinatorial processing,” is generally not available with tools that are designed specifically for conventional full substrate processing. Furthermore, it may be desirable to subject localized regions of the substrate to different processing conditions (e.g., localized deposition) in one step of a sequence followed by subjecting the full substrate to a similar processing condition (e.g., full substrate deposition) in another step.

Sputtering sources use “targets” to supply materials for sputter deposition of thin films. The target material comprises either an element, mixture of elements, alloy, or a compound such as an oxide, nitride, boride, sulfide, selenide, telluride, or carbide. These materials can be sputtered onto a substrate without chemical change. Alternatively, compounds such as oxides and nitrides can be formed by “reactive” sputtering wherein a reactive gas is mixed with an inert sputtering gas such as argon and reacts with the sputtered material typically at the substrate. For example, a metal oxide or metal nitride layer can be formed by sputtering metal in the presence of oxygen or nitrogen onto a substrate. Targets for sputtering can also be made from metal alloys and other mixtures of more than one material in order to form layers having mixed composition. Such targets are readily available from suppliers both as stock items and by custom order for unique mixture requirements.

“Mosaic” sputtering targets are also known and available from suppliers. A mosaic sputtering target comprises more than one material in the same target, but arranged in separate areas or sectors of the target rather than being intimately mixed, for example, by alloying. Mosaic sputtering targets have generally been used as another means of providing two materials such as two metals from a single target. A typical sputtering source uses a plasma that impinges on a large area of the target and provides a source of material from all areas of the target at once. There can be variability in relative composition of sputtered material when using a mosaic sputtering target, but, in most cases, this variability is undesirable because a fixed composition of sputtered material is required for most applications.

U.S. Pat. No. 6,878,242 to Wang and Seder discloses use of a rotating segmented sputtering target with a magnetron that sputters material from sequential segments as the target rotates. The device can be used to produce alternating layers of materials programmed by the segment arrangement, rotational speed, and the like.

### SUMMARY OF THE INVENTION

Embodiments of the present invention provide apparatuses using sputtering from a mosaic sputtering target for depositing layers onto a substrate and having the capability of depositing layers in a combinatorial manner. Accordingly, a sputtering source is provided comprising a device (such as a cathode) capable of causing the emission of material from a sputtering target, a mosaic sputtering target comprising a first region having a first composition, and a second region having a second composition; and a selection mechanism capable of selecting a composition of emitted material from the sputtering source. The composition of the emitted material can range from 0% to 100% of the first composition and from 0% to 100% of the second composition. In some embodiments, the emitted material is emitted from a fixed and stationary area on the mosaic sputtering target comprising at least a portion of the first region, at least a portion of the second region, or a combination thereof.

In some embodiments, the selection mechanism can comprise a movable magnetron which can be positioned to cause material to be selectively emitted from the first region, the second region, or a combination thereof, i.e., material can be emitted from both regions in any desired combination to produce a particular composition comprising the component materials present in the first and second regions. In some embodiments, the selection mechanism can comprise a selection aperture which can be positioned to selectively pass emitted material from the first region, the second region, or a combination thereof. If desired, the selection mechanism can comprise two or more selection apertures.

In some embodiments, the mosaic sputtering target can also comprise three or more regions, each having distinct compositions. The composition of emitted material from the sputtering source can then comprise a range of compositions from 0% to 100% of the first composition, from 0% to 100% of the second composition, and from 0% to 100% of the third composition. Similarly, if four or more distinct compositions are present in a single mosaic sputtering target, the composition of emitted material from the sputtering source can comprise a range of compositions from 0% to 100% of each composition. In some embodiments, the mosaic sputtering target can comprise two or more regions having the same composition as the first region or the second region, i.e., the distinct compositions can be formed in a repeating or random pattern throughout the mosaic sputtering target.

Embodiments of the present invention further include apparatuses for performing physical vapor deposition. Embodiments of the apparatuses can comprise a process chamber; one or more sputtering sources disposed within the process chamber; a substrate support disposed within the process chamber, the substrate support operable to support a substrate; a shield positioned between the sputtering sources and the substrate, the shield comprising a substrate aperture positioned between each sputtering source and the substrate, and a transport system integrated with the substrate support capable of positioning the substrate such that one of a plurality of site isolated regions on the substrate can be exposed to sputtered material through the substrate aperture positioned between each sputtering source and the substrate. The sputtering source can comprise a mosaic sputtering target and selection mechanism for selecting a composition of emitted material from the sputtering source.

In some embodiments, the plurality of site isolated regions on the substrate can be exposed to material emitted from the sputtering source or sources using a set of process parameters that can be varied in a combinatorial manner. The process parameters comprise one or more sputtering parameters, sputtering atmosphere parameters, substrate parameters, or combinations thereof. The process parameters can be varied such that each combination of sputtering parameters and substrate parameters can be tested independently. The sputtering parameters comprise exposure times, power, composition of material emitted from the sputtering source, target-to-substrate spacing, or combinations thereof. The sputtering atmosphere parameters comprise total pressure, carrier gas composition, carrier gas flow rate, reactive gas composition, reactive gas flow rate, or combinations thereof; wherein the reactive gas flow rate is greater than or equal to zero. The substrate parameters comprise substrate material, surface condition, substrate temperature, substrate bias, or combinations thereof.

In some embodiments, the sputtering source is oriented normal to the substrate, and can be placed in close proximity, such that the target is located from about 20 to about 100 mm from the substrate. In some embodiments, the apparatuses can further comprise two more sputtering sources. In some embodiments, the apparatuses can comprise a substrate aperture for each sputtering source, wherein a substrate aperture is positioned between each sputtering source and the substrate. In some embodiments, the apparatuses can further comprise an aperture shutter, wherein the aperture shutter is moveably disposed over the substrate aperture. In some embodiments, the apparatuses comprise a substrate support capable of providing independent substrate temperature control and applying a bias voltage.

Embodiments of the invention further include methods of forming a layer on a substrate. The methods can comprise exposing a first site-isolated region of a surface of a substrate to material emitted from a sputtering source using a first set of process parameters; exposing a second site-isolated region of the surface of the substrate to material emitted from the sputtering source using a second set of process parameters. During exposure to the sputtered material, the remaining area of the substrate can be protected from exposure to material from the sputtering source. The first and second set of process parameters can be varied in a combinatorial manner. The methods can further comprise exposing three or more site isolated regions of the substrate to material emitted from the sputtering source under distinct sets of process parameters.

In some embodiments, the methods utilize process parameters that can comprise one or more sputtering parameters, sputtering atmosphere parameters, substrate parameters, or combinations thereof. The process parameters can be varied such that each combination of sputtering parameters and substrate parameters can be tested independently. The sputtering parameters comprise, exposure times, power, composition of material emitted from the sputtering source, target-to-substrate spacing, or combinations thereof. The sputtering atmosphere parameters comprise total pressure, carrier gas composition, carrier gas flow rate, reactive gas composition, reactive gas flow rate, or combinations thereof; wherein the reactive gas flow rate is greater than or equal to zero. The substrate parameters comprise substrate material, surface condition, substrate temperature, substrate bias, or combinations thereof.

In some embodiments, the methods utilize a sputtering source comprising a mosaic sputtering target comprising a first region having a first composition, and a second region having a second composition; and a selection mechanism capable of selecting the composition of material to be emitted from the sputtering source such that the composition of emitted material can range from 0% to 100% of the first composition and from 0% to 100% of the second composition. In some embodiments, the mosaic sputtering target can also comprise three or more regions each having distinct compositions (i.e., the compositions are not repeated on different sites of the same target). The composition of emitted material from the sputtering source can then comprise a range of compositions from 0% to 100% of the first composition, from 0% to 100% of the second composition, and from 0% to 100% of the third composition. Similarly, if four or more distinct compositions are present in a single mosaic sputtering target, the composition of emitted material from the sputtering source can comprise a range of compositions from 0% to 100% of each composition. Preferably, at least two regions of the mosaic sputtering target have different compositions. In some embodiments, the mosaic sputtering target can comprise two or more regions having the same composition as the first region or the second region, i.e., the distinct compositions can be formed in repeating or random patterns throughout the mosaic sputtering target.

In some embodiments, the methods can further comprise forming layers on a substrate using an apparatus comprising two or more sputtering sources. In some embodiments, a plurality of layers can be formed on any site isolated region of the substrate. If desired, combinatorial processing can be utilized to prepare layers having distinct compositions.

### BRIEF DESCRIPTION OF THE DRAWINGS

FIG. 1 is a schematic diagram for implementing combinatorial processing and evaluation.

FIG. 2 is a schematic diagram for illustrating various process sequences using combinatorial processing and evaluation.

FIG. 3 shows an illustrative embodiment of a multi-source sputtering system.

FIG. 4 shows an illustrative embodiment of a high deposition rate sputtering system.

FIG. 5 shows an illustrative embodiment of a mosaic sputtering target used with a moveable magnetron.

FIG. 6 shows an illustrative embodiment of a mosaic sputtering target used with a selection aperture configured to select a region of the mosaic sputtering target for sputtering.

### DETAILED DESCRIPTION

Before the present invention is described in detail, it is to be understood that unless otherwise indicated this invention is not limited to specific layer compositions or surface treatments. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

### DEFINITIONS

The term “site-isolated” as used herein refers to providing distinct processing conditions, such as controlled temperature, flow rates, time of processing, composition of material emitted from a sputtering source, and the like. Site isolation may provide complete isolation between regions or relative isolation between regions. Preferably, the relative isolation is sufficient to provide a control over processing conditions within ±10%, within ±5%, within ±2%, within ±1%, or within ±0.1% of the intended conditions. Where one region is processed at a time, adjacent regions are generally protected from any exposure that would alter the substrate surface in a measurable way.

The term “site isolated region” is used herein to refer to a localized area on a substrate which is, was, or is intended to be used for processing or formation of a selected material made by processing conditions that are distinct from one site-isolated region to another. The site-isolated region can include one region and/or a series of regular or periodic regions predefined on the substrate. The site-isolated region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Substrate shapes and sizes can vary and include commonly used round wafers of 2″, 4″, 200 mm, or 300 mm in diameter.

The term “high-deposition-rate sputtering” as used herein refers to the use of a conventional sputtering source positioned much closer than normal (e.g., a target-to-substrate spacing of about 20 to about 100 mm) such that the flux of material from the sputtering source to the substrate is 2-4 times normal. Any sputtering source (rf or dc, reactive or inert) can be used.

The term “magnetron” as used herein refers to a magnet assembly used to control the flow of electrons and/or ions in a sputtering source. The magnet assembly can be either a permanent magnet or an electromagnet.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

Embodiments of the present invention provide mosaic sputtering targets for use in combinatorial processing. The mosaic sputtering targets can be used with apparatuses and methods disclosed in U.S. patent application Ser. No. 13/339,648, filed on Dec. 29, 2011, for systematic exploration of deposition process variables in a combinatorial manner, with the possibility of performing many process variations on a single substrate. The high deposition rate combinatorial processing along with the use of a mosaic sputtering target permits efficient use of target materials to optimize process conditions and design of novel materials.

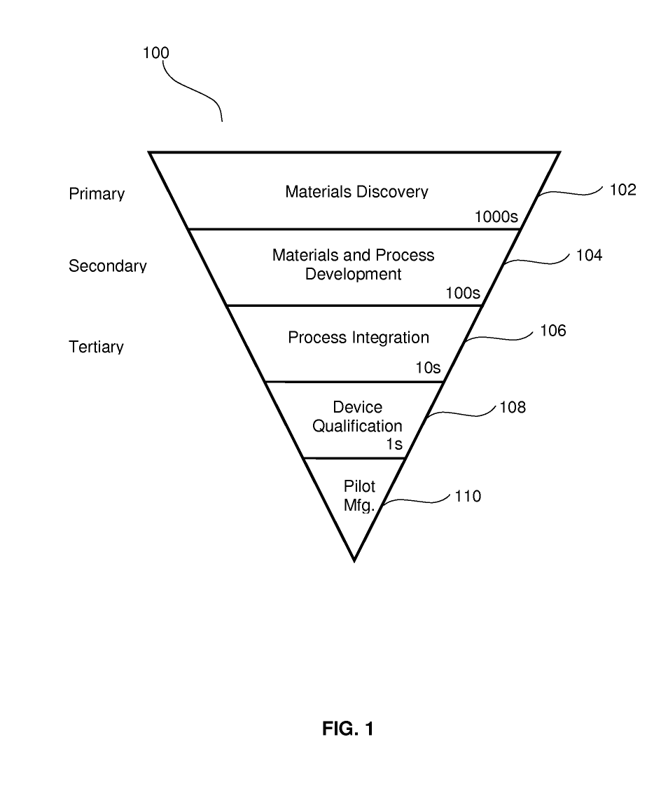

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention.

While the combinatorial processing varies certain materials, hardware details, or process sequences, the composition or thickness of the layers or structures or the actions, such as cleaning, surface preparation, deposition, surface treatment, etc. is substantially uniform through each discrete site-isolated region. Furthermore, while different materials or processes may be used for corresponding layers or steps in the formation of a structure in different regions of the substrate during the combinatorial processing, the application of each layer or use of a given process is substantially consistent or uniform throughout the different regions in which it is intentionally applied. Thus, the processing is uniform within a region (inter-region uniformity) and between regions (intra-region uniformity), as desired. It should be noted that the process can be varied between site-isolated regions, for example, where a thickness of a layer is varied or a material may be varied between the regions, etc., as desired by the design of the experiment.

The result is a series of site-isolated regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each site-isolated region are designed to enable valid statistical analysis of the test results within each region and across regions to be performed.

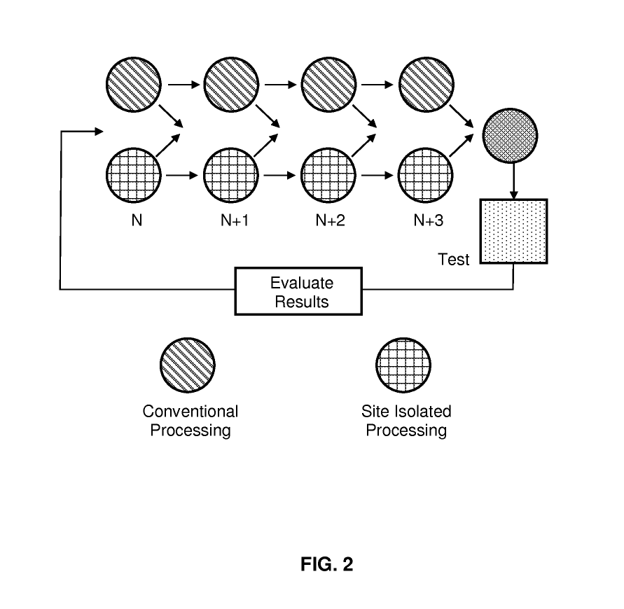

FIG. 2 is a simplified schematic diagram illustrating a general methodology for combinatorial process sequence integration that includes site-isolated processing and/or conventional processing in accordance with one embodiment of the invention. In one embodiment, the substrate is initially processed using conventional process N. In one exemplary embodiment, the substrate is then processed using site-isolated process N+1. During site-isolated processing, an HPC module may be used, such as the HPC module described in U.S. patent application Ser. No. 11/352,077, filed on Feb. 10, 2006. The substrate can then be processed using site-isolated process N+2, and thereafter processed using conventional process N+3. Testing is performed and the results are evaluated. The testing can include physical, chemical, acoustic, magnetic, electrical, optical, etc. tests. From this evaluation, a particular process from the various site-isolated processes (e.g. from steps N+1 and N+2) may be selected and fixed so that additional combinatorial process sequence integration may be performed using site-isolated processing for either process N or N+3. For example, a next process sequence can include processing the substrate using site-isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above process flows can be applied to entire monolithic substrates, or portions of the monolithic substrates.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, the order in which materials are deposited, hardware details of the gas distribution assembly, etc. It should be appreciated that these process parameters are exemplary and not meant to be an exhaustive list as other process parameters commonly used with remote plasma exposure systems may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Embodiments of the present invention provide sputtering sources with mosaic sputtering targets for use in PVD-based combinatorial processing, with the possibility of performing many process variations on a single substrate. The mosaic sputtering targets can be used with conventional PVD apparatuses using conventional sputtering methods, or can be used with apparatuses and methods disclosed in co-owned U.S. patent application Ser. No. 13/339,648, for systematic exploration of deposition process variables in a combinatorial manner. High deposition rate combinatorial processing along with the use of a mosaic sputtering target permits efficient use of resources and materials to optimize process conditions and design of novel materials. In the '648 application, a high deposition rate of sputtering is provided by locating the sputtering source much closer to the substrate than is practiced in prior art deposition methods, and by orienting the sputtering sources normal to the substrate, rather than tilting the sputtering source as is common in prior art deposition apparatuses. The mosaic sputtering targets can also be used with the high ionization sputtering gun described in co-owned U.S. patent application Ser. No. 13/281,316.

Embodiments of the present invention provide apparatuses that utilize sputtering from a mosaic sputtering target for depositing layers onto a substrate and that have the capability of depositing layers in a combinatorial manner. Accordingly, a sputtering source is provided comprising a device capable of causing the emission of material from a target (e.g., a cathode), a mosaic sputtering target comprising a first region having a first composition, and a second region having a second composition; and a selection mechanism capable of selecting a composition of emitted material from the sputtering source. The composition of the emitted material can range from 0% to 100% of the first composition and from 0% to 100% of the second composition. In some embodiments, the emitted material is emitted from a fixed and stationary area on the mosaic sputtering target, where the area comprises at least a portion of the first region, at least a portion of the second region, or a combination thereof. In some embodiments, the selection mechanism can comprise a movable magnetron which can be positioned to sputter material selectively from the first region, the second region, or a combination thereof, i.e., material can be emitted from both regions in any desired combination to produce a particular composition comprising the component materials present in the first and second regions. In some embodiments, the selection mechanism can comprise a selection aperture which can be positioned to selectively pass emitted material from the first region, the second region, or a combination thereof. If desired, the selection mechanism can comprise two or more selection apertures.

In some embodiments, the mosaic sputtering target can also comprise three or more regions each having distinct compositions. The composition of emitted material from the sputtering source can then comprise a range of compositions from 0% to 100% of the first composition, from 0% to 100% of the second composition, and from 0% to 100% of the third composition. Similarly, if four or more distinct compositions are present in a single mosaic sputtering target, the composition of emitted material from the sputtering source can comprise a range of compositions from 0% to 100% of each composition. In some embodiments, the mosaic sputtering target can comprise two or more regions having the same composition as the first region or the second region, i.e., the distinct compositions can be formed in a repeating or random pattern throughout the mosaic sputtering target.

Embodiments of the present invention further include apparatuses for performing physical vapor deposition. Embodiments of the apparatuses can comprise a process chamber; one or more sputtering sources disposed within the process chamber; a substrate support disposed within the process chamber, the substrate support operable to support a substrate; a shield positioned between the sputtering source and the substrate, the shield comprising a substrate aperture positioned under the sputtering source, and a transport system integrated with the substrate support, wherein the transport system is capable of positioning the substrate such that one of a plurality of site isolated regions on the substrate can be exposed to sputtered material through the substrate aperture positioned under each of the sputtering sources. The sputtering source can comprise a mosaic sputtering target and selection mechanism for selecting a composition of emitted material from the sputtering source.

The process chamber provides a controlled atmosphere (referred to as a “sputtering atmosphere”) such that sputtering can be performed at any gas pressure or gas composition necessary to perform the desired combinatorial processing. The sputtering atmosphere parameters comprise total pressure, carrier gas composition, carrier gas flow rate, reactive gas composition, reactive gas flow rate, or combinations thereof. The reactive gas flow rate can be greater than or equal to zero. The sputtering atmosphere typically comprises one or more inert gases such as neon, argon, krypton, or xenon. In some embodiments, the sputtering atmosphere further comprises one or more reactive gases such as oxygen, hydrogen, or nitrogen. Additional gases can be used as desired for particular applications.

In some embodiments, the sputtering source is oriented substantially normal to the substrate, and can be placed in close proximity, such that the target is located from about 20 to about 100 mm from the substrate. In some embodiments, the apparatuses can further comprise two more sputtering sources. In some embodiments, the apparatuses can comprise a substrate aperture for each sputtering source, wherein a substrate aperture is positioned between each sputtering source and the substrate. In some embodiments, the apparatuses can further comprise an aperture shutter, wherein the aperture shutter is moveably disposed over the substrate aperture. The substrate aperture typically has an opening smaller than the substrate so that discrete regions of the substrate can be subjected to distinct process parameters in a combinatorial manner. However, there is no particular limit on the size of the substrate aperture.

The substrate parameters comprise substrate temperature, substrate bias, or combinations thereof. Accordingly, in some embodiments, the apparatuses comprise a substrate support capable of providing independent substrate temperature control up to 500 C, and applying a bias voltage of up to −300 V.

Substrates can be a conventional round 200 mm, 300 mm, or any other larger or smaller substrate/wafer size. In other embodiments, substrates may be square, rectangular, or other shape. One skilled in the art will appreciate that substrate may be a blanket substrate, a coupon (e.g., partial wafer), or even a patterned substrate having predefined regions. In some embodiments, a substrate may have regions defined through the processing described herein.

Embodiments of the invention further include methods of forming a layer on a substrate using sputtering sources comprising mosaic sputtering targets. The methods can be utilized with conventional processing or with combinatorial processing. The methods can comprise exposing a first site-isolated region of a surface of a substrate to material from a sputtering source using a first set of process parameters, exposing a second site-isolated region of the surface of the substrate to material from the sputtering source using a second set of process parameters, and varying the first and second set of process parameters in a combinatorial manner. During exposure of the surface of the substrate to the sputtering source, the remaining area of the substrate is not exposed to the material from the sputtering target, enabling site-isolated deposition of sputtered material onto the substrate. The methods can further comprise exposing three or more site isolated regions of the substrate to material from the sputtering source using distinct sets of process parameters. There is no particular limit on the number of site isolated regions that can be exposed to distinct processing parameters, and the method is limited only by the size of the substrate chosen and the size of the site isolated region selected for testing. If necessary, additional substrates can be utilized in order to test a full complement of particular combinatorial process parameters.

The skilled artisan will recognize that the control of layer composition on a substrate can be performed using the mosaic sputtering targets with the sputtering sources and apparatuses described herein. The composition of layers can be affected by the composition of each region on the sputtering target (expressible as weight percent, atomic percent, or volume percent), the relative amount of material provided to a substrate from each region of the sputtering target, as well as the relative sputtering efficiency of different elements and compounds.

In some embodiments, the process parameters can comprise one or more sputtering parameters, sputtering atmosphere parameters, substrate parameters, or combinations thereof. The process parameters can be varied such that each combination of sputtering parameters, sputtering atmosphere parameters, and substrate parameters can be tested independently. The sputtering parameters comprise, exposure times, power, composition of material emitted from the sputtering source, target-to-substrate spacing, or combinations thereof. The sputtering atmosphere parameters comprise total pressure, carrier gas composition, carrier gas flow rate, reactive gas composition, reactive gas flow rate, or combinations thereof; wherein the reactive gas flow rate is greater than or equal to zero. The substrate parameters comprise substrate material, surface condition, substrate temperature, substrate bias, or combinations thereof. In some embodiments, the plurality of site isolated regions on the substrate can be exposed to sputtered material using a set of process parameters that can be varied in a combinatorial manner. The process parameters can comprise the same parameters listed above. The process parameters can be varied such that each combination of sputtering parameters and substrate parameters can be tested independently.

In some embodiments, the sputtering source comprises a mosaic sputtering target comprising a first region having a first composition, and a second region having a second composition; and a selection mechanism capable of selecting the composition of material to be emitted from the sputtering source such that the composition of sputtered material can range from 0% to 100% of the first composition and from 0% to 100% of the second composition. In some embodiments, the mosaic sputtering target can also comprise three or more regions each having distinct compositions (i.e., the compositions are not repeated on different sites of the same target). The composition of emitted material from the sputtering source can then comprise a range of compositions from 0% to 100% of the first composition, from 0% to 100% of the second composition, and from 0% to 100% of the third composition. Similarly, if four or more distinct compositions are present in a single mosaic sputtering target, the composition of emitted material from the sputtering source can comprise a range of compositions from 0% to 100% of each composition. The percent composition is used in the conventional sense, such that the relative compositions add up to a total of 100%. The relative composition can be specified by any convenient measure, such as atom percent, weight percent or volume percent.

Preferably, at least two regions of the mosaic sputtering target have different compositions. In some embodiments, the mosaic sputtering target can comprise two or more regions having the same composition as the first region or the second region, i.e., the distinct compositions can be formed in repeating or random patterns throughout the mosaic sputtering target. Similarly, with three or more regions of distinct composition, the compositions can be arranged in repeating or random patterns throughout the mosaic sputtering target.

In some embodiments, one region is used at a time so that emitted material is provided from a single region. Different regions can be used to provide varying compositions for different layers on a substrate. In some embodiments, the selection mechanism can be configured so that emitted material is provided from portions of two or more regions to produce layers having mixed compositions including material from more than one region on the sputtering target.

In some embodiments, the methods can comprise forming layers on a substrate using an apparatus comprising two or more sputtering sources. In some embodiments, the methods can further comprise depositing additional layers onto any site-isolated region to build multi-layered structures if desired. In this manner, a plurality of process parameters to deposit one or a plurality of layers can be explored on a single substrate using distinct process parameters. If desired, combinatorial processing can be utilized to prepare layers having distinct compositions.

Software is provided to control the process parameters for each substrate for the combinatorial processing. Examples of process parameters that can be controlled by software include one or more sputtering parameters, sputtering atmosphere parameters, substrate parameters, or combinations thereof. The process parameters can be varied such that each combination of sputtering parameters and substrate parameters can be tested independently. The sputtering parameters comprise, exposure times, power, composition of material emitted from the sputtering source, target-to-substrate spacing, or combinations thereof. The sputtering atmosphere parameters comprise total pressure, carrier gas composition, carrier gas flow rate, reactive gas composition, reactive gas flow rate, or combinations thereof; wherein the reactive gas flow rate is greater than or equal to zero. The substrate parameters comprise substrate material, surface condition, substrate temperature, substrate bias, or combinations thereof.

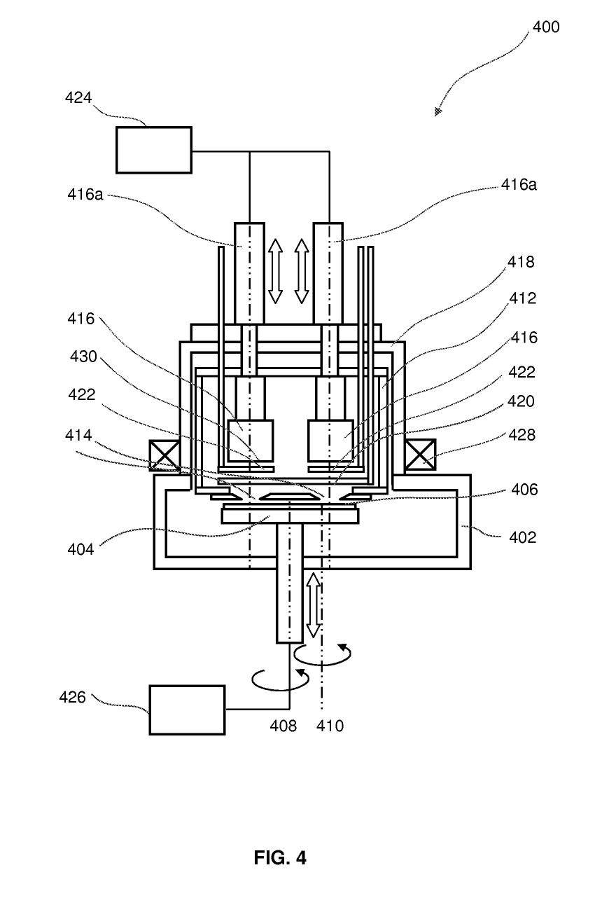

Embodiments of the present invention are provided in FIGS. 4-6 with an orientation having sputtering sources disposed above substrates, with optional substrate apertures, selection apertures, and shutters disposed between the sputtering sources and substrates, and having magnetrons disposed above sputtering targets. The common orientation shown in these figures is solely for illustration and is not meant to imply an orientation relative to gravity. The skilled artisan will recognize that the instant invention can be positioned in any orientation relative to gravity.

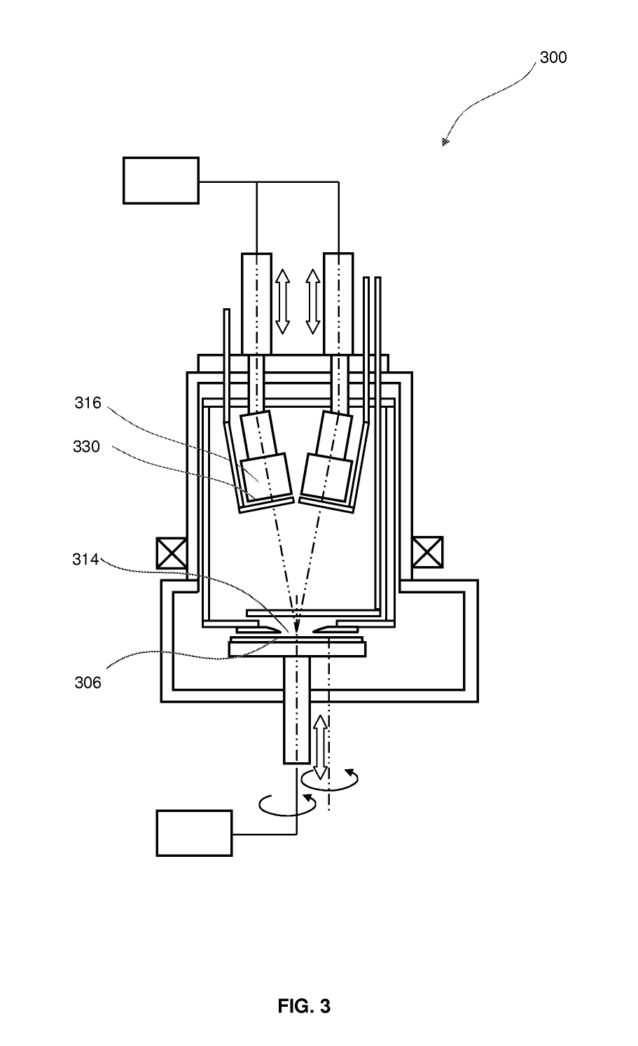

FIG. 3 is a simplified schematic diagram illustrating some embodiments of the present invention. A sputter chamber 300 is configured to perform combinatorial processing using a plurality of sputtering sources each having a sputtering source comprising a mosaic sputtering target with selection mechanisms as described above. A plurality of sputtering sources 316 with mosaic sputtering targets 330 are shown positioned at an angle so that they can be aimed through a single substrate aperture 314 to a site-isolated region on a substrate 306. The sputtering sources 316 are positioned such that the target is at least about 80 mm from the substrate 306 to ensure uniform flux to the substrate within the site-isolated region. Typically the target is positioned from about 80 mm to about 300 mm from the substrate. Additional components shown are similar to components in the illustrative embodiment shown in FIG. 4.

FIG. 4 is a simplified schematic diagram illustrating a sputter chamber configured to perform combinatorial processing in accordance with some embodiments of the present invention. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support can be useful for combinatorial processing using site-isolated mechanisms. Other substrate supports, such as an X-Y table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support 404 and substrate 406, and produces a bias voltage on substrate 406. Substrate 406 can be a conventional round 200 mm, 300 mm, or any other larger or smaller substrate/wafer size. In other embodiments, substrate 406 can be square, rectangular, or other suitable shape. One skilled in the art will appreciate that substrate 406 can be a blanket substrate, a coupon (e.g., partial wafer), or even a patterned substrate having predefined regions. In another embodiment, substrate 406 can have regions defined through the processing described herein.

Top chamber portion 418 of chamber 400 in FIG. 4 includes shield 412, which defines a confinement region over a radial portion of substrate 406. Shield 412 is a sleeve having a base (optionally integrated with the shield) and an optional top within chamber 400 that can be used to confine a plasma generated therein. The generated plasma dislodges atoms from a mosaic sputtering target 430 (causing material to be emitted from the sputtering target) and the sputtered material is deposited on a site-isolated region of the substrate 406. Deposition can be performed in an inert gas atmosphere (e.g., an argon carrier gas) to deposit materials such as pure metals, or in the presence of reactive gases such as nitrogen or oxygen to form molecules such as metal oxides or metal nitrides at the substrate surface. These gases are referred to as sputtering gases. Neutral atoms or molecules (optionally in an excited electronic state) can be deposited. Alternatively, ions can be deposited, in which case a substrate bias voltage can be used advantageously to tune the energy of the ions arriving at the site isolated region. Chamber pressure and gas flow rates can be adjusted to control the process; for example, the stoichiometry of layers formed in a reactive atmosphere can be tuned by adjusting the relative flow rate of the reactive gas(es).

Shield 412 is capable of being moved in and out of chamber 400, i.e., the shield is a replaceable insert. Shield 412 includes an optional top portion, sidewalls and a base. In some embodiments, shield 412 is configured in a cylindrical shape, however, the shield may be any suitable shape and is not limited to a cylindrical shape.

The base of shield 412 includes a plurality of substrate apertures 414 through which one or more site isolated region of the surface of substrate 406 is exposed for deposition or some other suitable semiconductor processing operations. The center of each aperture can be substantially aligned with the center of its corresponding sputtering source. Aperture shutter 420 is moveably disposed over the base of shield 412. In some embodiments, aperture shutter 420 can be moved across a bottom surface of the base of shield 412 in order to cover or expose one or more substrate apertures 414. Typically, only one substrate aperture is uncovered at any one time to prevent cross-contamination between site-isolated regions. In some embodiments, aperture shutter 420 is controlled through an arm extension which moves the aperture shutter to expose or cover a substrate aperture 414. It should be noted that although a single substrate aperture per sputtering source is illustrated, multiple substrate apertures may be included for each sputtering source. Each substrate aperture can be associated with a dedicated aperture shutter or an aperture shutter can be configured to cover more than one substrate aperture simultaneously or separately. Alternatively, substrate aperture 414 can be a larger opening and aperture shutter 420 can extend with that opening to either completely cover the substrate aperture or place one or more fixed apertures within that opening for processing the defined regions. The dual rotary substrate support 404 is useful to the site-isolating mechanism, and allows any location of the substrate or wafer to be placed under the substrate aperture 414. Hence, site-isolated deposition is possible at any location on the wafer/substrate.

A sputtering source shutter, 422 can also be included. Sputtering source shutter 422 functions to seal off a deposition source when the deposition source may not be used for the processing in some embodiments. For example, two sputtering sources 416 with sputtering targets 430 are illustrated in FIG. 4. Sputtering sources 416 are moveable in a vertical direction so that one or both of the sources can be lifted from the slots of the shield. While two sputtering sources are illustrated, any number of sputtering sources can be included, constrained only by space limitations, e.g., one, three, four or more sputtering sources can be included. Typical embodiments for combinatorial processing can include 4 to 6 sputtering sources. Where more than one sputtering source is included, the plurality of sputtering sources may be referred to as a cluster of sputtering sources. In some embodiments, one or more sputtering sources can utilize conventional sputtering targets. In some embodiments, one or more of the sputtering sources can utilize mosaic sputtering targets. Sputtering source shutter 422 can be moved to isolate the lifted sputtering sources from the processing area defined within shield 412. In this manner, the sputtering sources can be isolated from certain processes when desired. It should be appreciated that sputtering source shutter 422 can be integrated with the top of the shield 412 to cover the opening as the sputtering source is lifted or an individual cover plate 422 can be used for each site-isolated region.

Top chamber portion 418 of chamber 400 of FIG. 4 includes sidewalls and a top plate which house shield 412. Arm extensions 416a, which are fixed to sputtering sources 416 can be attached to a suitable drive, e.g., lead screw, worm gear, etc., configured to vertically move sputtering sources 416 toward or away from a top plate of top chamber portion 418. In typical use for sputtering at a high deposition rate, the sputtering source is positioned, such that the target is located about 20-100 mm above the substrate, which is closer than the typical spacing of 100-300 mm used in most sputtering systems.

Chamber 400 includes magnet 428 disposed around an external periphery of the chamber. Magnet 428 is located in a region defined between the bottom surface of sputter sources 416 and a top surface of substrate 406. Magnet 428 may be either a permanent magnet or an electromagnet. It should be appreciated that magnet 428 is utilized to improve ion guidance as the magnetic field distribution above substrate 406 is re-distributed or optimized to guide metal ions onto the substrate.

Some embodiments of the present invention provide methods of depositing layers on a substrate at a high deposition rate, for example, using the specific apparatus shown in FIG. 4. Compared to conventional sputtering using the apparatus configuration of FIG. 3, these embodiments can achieve deposition rates of about 0.5 Å/s, or 2-4 times the rate of conventional sputtering. A 900 Å electrode layer can be formed in about 30 min instead of 2 hr. In addition, the layer can exhibit substantially higher film quality with fewer contaminants such as oxygen which can increase the resistivity of a conductive layer.

Embodiments of the present invention can be practiced using any configuration of sputtering sources suitable for HPC processing such as the embodiments illustrated in FIGS. 3 and 4. Additional process control can be provided by use of a “mosaic” target. A mosaic sputtering target comprises regions (areas) on a sputtering target of distinct composition in distinct locations on the target. Two or more distinct material compositions can be provided. In some embodiments, the distinct compositions can be pure atomic materials such as pure metals. In other embodiments, the distinct compositions are themselves alloys, compounds, or mixtures comprising a plurality of elements. The material composition in a region is generally uniform through the thickness of the mosaic sputtering target such that as material is consumed (used) by sputtering, the composition of each region remains constant.

The regions of a mosaic sputtering target can be of any convenient shape, and the number of regions and the number of distinct regions can vary. For example, regions can comprise pie-shaped sectors, a set of annular rings, square tiles, or hexagonal tiles. The mosaic sputtering target can comprise any number of distinct regions limited only by practicality and convenience, and can comprise, for example, two distinct regions, three distinct regions, four distinct regions, ten distinct regions, and the like. In addition, each distinct region can be repeated on a target any number of times. Region size and shape can be chosen to be compatible with a method of selecting sputtered material delivered to a substrate to material from a distinct region. Exemplary methods such as a movable magnetron or a selection aperture are described below.

Mixed compositions within a region on a mosaic sputtering target can be provided using any convenient assembly method compatible with the materials to be used. For example, in some embodiments, pluralities of metals can be alloyed, and a region on a mosaic sputtering target can comprise a uniform alloy. In other embodiments, a plurality of materials can be formed into particles, mixed, and then sintered to form a region on a mosaic sputtering target. In other embodiments, a region on a mosaic sputtering target can be assembled from a plurality of smaller tiles each comprising one of the mixture components. A slight gap between side surfaces of different materials can be tolerated, because sputtering is usually off-angle due to Lorentz force, i.e., ion impingement is not perpendicular to the top surface of a target surface. In preferred embodiments, the gaps are small enough that ions do not penetrate gaps to the depth of any underlying support surface, so that sputtering occurs from the tile materials only.

The mosaic sputtering target composition is not limited to any particular materials, and can comprise any sputterable material. In some embodiments, a region of the mosaic sputtering target comprises an element such as a metal or semiconductor, or a compound such as an oxide, nitride, oxynitride, silicide, boride, sulfide, selenide, telluride, or carbide of a metal or semiconductor. Mixtures of these compounds can also be provided.

In some embodiments, distinct regions on a mosaic sputtering target can comprise distinct materials, for example Ti and Ni. In other embodiments, distinct regions on a mosaic sputtering target can comprise the same materials in different proportions, for example, one region comprising 60% Ti/40% Ni (atomic percent) and a second region comprising 40% Ti/60% Ni, and the like. The skilled artisan will recognize that mosaic sputtering targets can be constructed in numerous permutations and combinations according to the needs of particular combinatorial process development experiments.

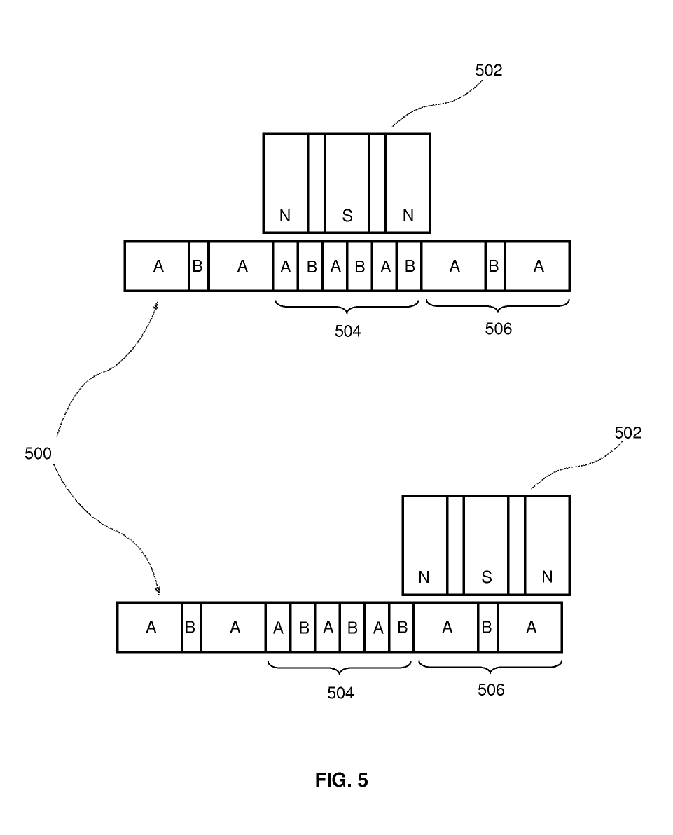

In some embodiments, a mosaic sputtering target for HPC processing is used with a sputtering source having a moveable magnetron. FIG. 5 illustrates one configuration of a mosaic sputtering target 500 adjacent to a moveable magnetron. A magnetron 502 is shown having magnetic field dimensions and corresponding target erosion area dimensions comparable to the size of regions 504 and 506 on sputtering target 500 which has a plurality of distinct regions. The magnetron 502 is movable so that sputtering can be performed from one distinct region at a time or from a combination of distinct regions at a time. For example, the target in FIG. 5 illustrates regions 504 and 506 comprising varying proportions of two compositions ‘A’ and ‘B’. As illustrated, a central region 504 comprises equal portions of ‘A’ and ‘B’, while an outer region 506 comprises about 85% ‘A’ and 15% ‘B’. When the magnetron is positioned over region 504, the sputter source can deliver a mixture comprising equal portions of ‘A’ and ‘B’; when the magnetron is positioned over region 506, the sputter source can deliver a mixture comprising about 85% ‘A’ and 15% ‘B’. Not illustrated is the additional option of positioning the magnetron at an intermediate position so as to sputter some material from region 504 and some material from region 506 such that the sputter source can deliver an intermediate composition such as 65% ‘A’ and 35% T′.

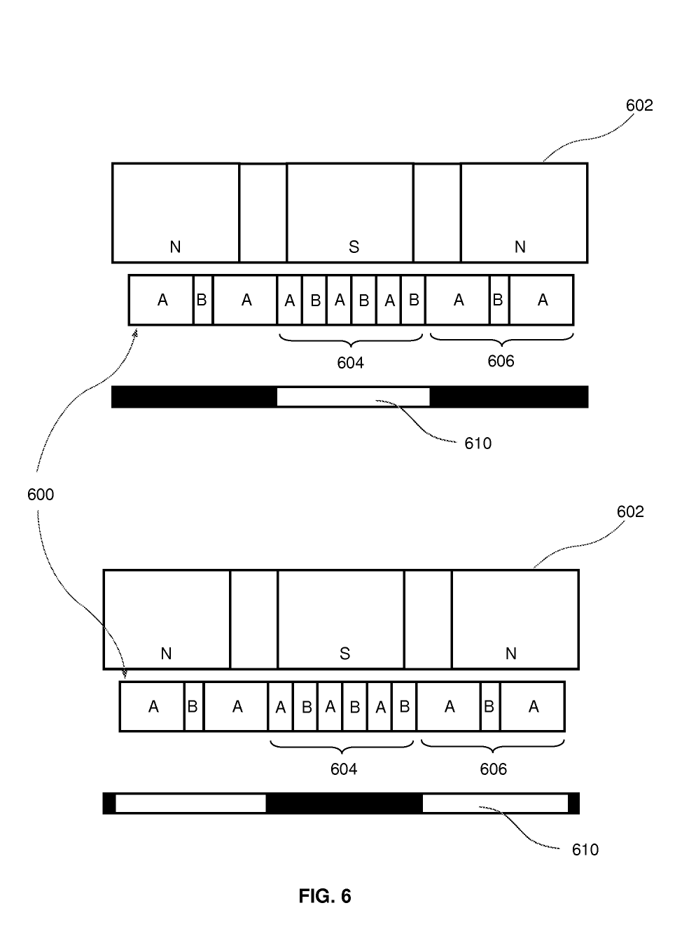

In some embodiments, a mosaic sputtering target for HPC processing is used with a selection aperture as shown in FIG. 6. The magnetron 602, can be stationary or rotating and is capable of eroding substantially all of the area of the mosaic sputtering target 600 as in embodiments of sputtering sources using uniform sputtering targets. To select a particular subset of the emitted material for delivery to a substrate, a selection aperture 610 can be positioned adjacent to the mosaic sputtering target, and between the mosaic sputtering target and the substrate apertures 314 and 414 shown in FIGS. 3 and 4. The selection aperture 610 can be positioned or otherwise adjusted so that the open area is adjacent to one distinct region of the mosaic sputtering source at any given time. For example, as shown in FIG. 6, when the selection aperture is positioned under region 604, the sputtering source can deliver a mixture comprising equal portions of ‘A’ and ‘B’; when the selection aperture is positioned under region 606, the sputtering source can deliver a mixture comprising about 85% ‘A’ and 15% ‘B’. Not illustrated is the additional option of positioning the selection aperture at an intermediate position so as to select some material from region 604 and some material from region 606 such that the sputter source can deliver an intermediate composition such as 65% ‘A’ and 35% ‘B’.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A sputtering source comprising
a sputtering target,
a device capable of causing emission of material from the sputtering target, and
a selection mechanism capable of selecting the composition of the emitted material from the sputtering source;
wherein the sputtering target comprises
a first region having a first composition, and
a second region having a second composition;
wherein the composition of emitted material from the sputtering source can range from 0% to 100% of the first composition and from 0% to 100% of the second composition; and
wherein the emitted material is emitted from a fixed and stationary area on the sputtering target comprising at least a portion of the first region, or at least a portion of the second region, or a combination thereof.

2. The sputtering source of claim 1, wherein the selection mechanism comprises a movable magnetron which can be positioned to cause material to be emitted selectively from the first region, the second region, or a combination thereof.

3. The sputtering source of claim 1, wherein the selection mechanism comprises a selection aperture which can be positioned to selectively pass emitted material from the first region, the second region, or a combination thereof.

4. The sputtering source of claim 1, wherein the sputtering target further comprises three or more regions, each region having different compositions.

5. The sputtering source of claim 4, wherein the composition of emitted material from the sputtering source comprises a range of compositions from 0% to 100% of each composition.

6. The sputtering source of claim 1, wherein the sputtering target comprises three or more regions, wherein at least two of the regions have the same composition.

7. An apparatus for physical vapor deposition comprising
a process chamber;
one or more sputtering sources according to claim 1 disposed within the process chamber;
a substrate support disposed within the process chamber, the substrate support operable to support a substrate;
a shield positioned between the sputtering source and the substrate, the shield comprising a substrate aperture positioned between each sputtering source and the substrate, and
a transport system connected to the substrate support capable of positioning the substrate such that one of a plurality of site isolated regions on the substrate can be exposed to material emitted from the sputtering source through the substrate aperture.

8. The apparatus of claim 7, wherein the apparatus is operable to vary a set of process parameters in a combinatorial manner among the plurality of site isolated regions.

9. The apparatus of claim 8, wherein the process parameters comprise one or more sputtering parameters, sputtering atmosphere parameters, substrate parameters, or combinations thereof.

10. The apparatus of claim 9, wherein the sputtering parameters comprise, exposure times, power, composition of material emitted from the sputtering source, target-to-substrate spacing, or combinations thereof.

11. The apparatus of claim 9, wherein the sputtering atmosphere parameters comprise total pressure, carrier gas composition, carrier gas flow rate, reactive gas composition, reactive gas flow rate, or combinations thereof; wherein the reactive gas flow rate is greater than or equal to zero.

12. The apparatus of claim 9, wherein the substrate parameters comprise substrate material, surface condition, substrate temperature, substrate bias, or combinations thereof.

13. The apparatus of claim 7, further comprising two more sputtering sources.

14. The apparatus of claim 13, further comprising a substrate aperture for each sputtering source, wherein each substrate aperture is disposed between each sputtering source and the substrate.

15. The apparatus of claim 7, further comprising a shutter, wherein the shutter is moveably disposed over the substrate aperture.

16. The apparatus of claim 7, wherein the substrate support is capable of providing independent substrate temperature control and applying a bias voltage.

17. A method of forming a layer on a substrate comprising
exposing a first site-isolated region of a surface of a substrate to material emitted from a sputtering source using a first set of process parameters;
exposing a second site-isolated region of the surface of the substrate to material emitted from the sputtering source using a second set of process parameters; and
varying the first and second set of process parameters in a combinatorial manner;
wherein the sputtering source comprises
a sputtering target,
a device capable of causing the emission of material from the sputtering target, and
a selection mechanism;
wherein the sputtering target comprises
a first region having a first composition, and
a second region having a second composition; and
wherein the selection mechanism is capable of selecting the composition of material emitted from the sputtering source such that the composition can range from 0% to 100% of the first composition and from 0% to 100% of the second composition.

18. The method of claim 17, further comprising exposing three or more site isolated regions of the substrate to material from the sputtering source under different sets of process parameters.

19. The method of claim 17, wherein the process parameters comprise one or more sputtering parameters, sputtering atmosphere parameters, substrate parameters, or combinations thereof.

20. The method of claim 17, wherein the sputtering parameters comprise exposure times, power, composition of material emitted from the sputtering source, target-to-substrate spacing, or combinations thereof.
